(19) United States
(12) Patent Application Publication
(10) Pub. No.: US 2011/0111594 A1
(43) Pub. Date: May 12, 2011

(54) WAFER BONDING METHOD

(75) Inventor: Daisuke KIKUCHI, Tokyo (JP)

(73) Assignee: SUMCO CORPORATION, Tokyo (JP)

(21) Appl. No.: 12/942,416

(22) Filed: Nov. 9, 2010

(30) Foreign Application Priority Data
Nov. 11, 2009 (JP) 2009-258431

(51) Int. Cl. H01L 21/306; H01L 21/3065; H01L 21/304

(52) U.S. Cl. 438/691; 257/E21.218; 257/E21.224; 257/E21.237

(57) ABSTRACT

Even for the case where a CVD oxide film is interposed at a bonding interface, as a pre-processing of bonding a first wafer and a second wafer, at least the surface roughness of the CVD oxide film of the first wafer is made small after removing organic substances. Therefore, it is possible to prevent void occurrence which is caused by the organic substances existing at and the roughness of the bonding interface of the two wafers.

### CROSS-REFERENCE TO RELATED APPLICATIONS

The present application claims priority under 35 U.S.C. §119 of Japanese Application No. 2009-258431, filed on Nov. 11, 2009, the disclosure of which is expressly incorporated by reference herein in its entirety.

### BACKGROUND OF THE INVENTION

1. Field of the Invention

The present disclosure relates to a wafer bonding method. More specifically, the present disclosure relates to a wafer bonding method for bonding a wafer having a CVD oxide film formed on a surface thereof and a silicon wafer having a silicon surface.

2. Description of Related Art

As a manufacturing method for a bonded SOI (Silicon On Insulator) wafer in which two wafers are bonded via an oxide film, for example, Laid-Open Patent Publication No. 2000-30992 is known. This technology utilizes a hydrogen ion delamination method, and is directed to void reduction at a bonding interface by bonding two wafers at a carbon concentration (organic substance contamination concentration) of 5×10¹⁴ atoms/cm² or less at the bonding interface. In the hydrogen ion delamination method, a first wafer being implanted with hydrogen ion (or a light element ion) at a location of a predetermined depth after an oxide film is formed thereon, and a second wafer having no oxide film formed thereon, are bonded. The resulting bonded wafer is subjected to a heat-treatment. Thereby, a portion of the first wafer is delaminated from the ion implantation region to form an active layer.

In Laid-Open Patent Publication No. 2000-30992, in order to achieve a carbon concentration of 5×10¹⁴ atoms/cm² or less, as a pre-processing of the bonding, the bonding surfaces of the two wafers are subjected to an SC1 cleaning, an SC2 cleaning, and a cleaning that combines an ozone cleaning and a sulfuric acid-hydrogen peroxide cleaning. It is known that organic substance contamination at the bonding interface is closely related to the bonding failure of a bonded wafer. Carbon concentration is an indicator of organic substance contamination. When organic substance contamination occurs at the bonding interface, organic substances trapped at the bonding interface become gasified when subjected to a high temperature bonding heat treatment. When the gas pressure is stronger than the bonding strength and the rigidity of silicon, a void (a not-bonded area) is generated.

However, Laid-Open Patent Publication No. 2000-30992 was a technology effective only for bonding between wafers having relatively a low organic substance contamination level and a small surface roughness such as a wafer having a thermally oxidized film formed on a surface thereof and a wafer having no thermally oxidized film. That is, the void reduction was insufficient for bonding between a CVD oxide film and a silicon that is commonly performed in a device process. This is because a CVD oxide film has a lower density than a thermally oxidized film, and thus has a larger surface roughness and also more impurities.

### SUMMARY OF THE INVENTION

To address the above described problems, the inventor of the present disclosure has conducted intensive studies, and found that, even when the oxide film interposed at the bonding interface is a CVD oxide film, when, prior to the bonding, the surface of the CVD oxide film is subjected to an organic substance removal processing, which includes a cleaning and a heat treatment, and a surface roughness reduction processing, which includes a touch polish (light polish) and a plasma treatment, it is possible to prevent bonding failure and void occurrence due to organic substances and surface roughness, and thus accomplished the present disclosure.

A non-limiting feature of the present disclosure is to provide a wafer bonding method that enables bonding and also inhibits void occurrence in wafer bonding between a CVD oxide film and a silicon for which bonding is difficult.

A non-limiting feature of the present disclosure provides a wafer bonding method for bonding a first wafer and a second wafer via a CVD oxide film, the first wafer having the CVD oxide film formed on a surface thereof and the second wafer being made of silicon. In this wafer bonding method, as a pre-processing of the bonding, of a bonding interface of the first wafer and a bonding interface of the second wafer, at least the bonding interface of the first wafer is subjected to an organic substance removal processing and a surface roughness reduction processing. Here, the organic substance removal processing is at least one of a cleaning and a heat treatment. The cleaning uses any one of an SC1 cleaning solution, an SC2 cleaning solution and a two-step cleaning solution, the two-step cleaning solution being made of a HF solution for a first cleaning and an ozone water for a second cleaning, which is performed after the first cleaning. The heat treatment is performed in an atmosphere of an oxygen gas or a nitrogen gas at a temperature of 200° C. or above. The surface roughness reduction processing is at least one of a touch polish and a plasma treatment. The touch polish involves a polishing amount of 200-2000 Å, and the plasma treatment involves exposing at least the bonding interface of the first wafer to a high-frequency plasma of 50-500 W for 5-60 seconds.

According to a non-limiting feature of the present disclosure, prior to bonding the first wafer and the second wafer, of the first wafer and the second wafer, at least the bonding interface (the surface of the CVD oxide film) of the first wafer is subjected to an organic substance removal processing. Specifically, at least one of a cleaning and a heat treatment is performed. The cleaning uses any one of an SC1 cleaning solution, an SC2 cleaning solution and a two-step cleaning solution, the two-step cleaning solution being made of a HF solution for a first cleaning and an ozone water for a second cleaning, and the heat treatment being performed in an atmosphere of an oxygen gas or a nitrogen gas at a temperature of 200° C. or above.

Further, of the first wafer and the second wafer, at least the bonding interface of the first wafer is subjected to a surface roughness reduction processing. Specifically, at least one of a touch polish and a plasma treatment is performed. The touch polish involves a polishing amount of 200-2000 Å, and the plasma treatment involves exposing the surface to a high-frequency plasma of 50-500 W for 5-60 seconds. Next, the two bonding interfaces are superimposed to bond the first wafer and the second wafer. At this point, at least the bonding surface (the surface of the CVD oxide film) of the first wafer has organic substances removed and surface roughness also improved. Therefore, even for a wafer bonding between a CVD oxide film and a silicon, for which bonding is difficult, bonding becomes possible, and it is also possible to inhibit void occurrence at the bonding interface.

As the first wafer and the second wafer, for example, single crystal silicon wafers obtained by wafer-processing a single crystal silicon ingot pulled using the Czochralski method can be adopted. On a surface of the first wafer, a CVD oxide film is formed. The CVD oxide film can also be formed on a backside surface of the wafer. The diameter of the first wafer and the second wafer is arbitrary. For example, it can be 100 mm, 125 mm, 150 mm, 200 mm, 300 mm, or even 450 mm or above.

As bonded wafers, various bonded SOI wafers involving film thinning of a wafer on an active layer side can be adopted. Examples include a common bonded SOI wafer in which, after bonding two wafers, film thinning is performed to the wafer on the active layer side by grinding, polishing or etching to obtain an active layer. In addition, a bonded SOI wafer obtained by using a hydrogen ion delamination method (smart cut method) can also be adopted. As a bonded wafer, a bonded wafer that does not involve film thinning can also be adopted.

Here, a method of manufacturing an SOI wafer using a hydrogen ion delamination method is explained. First, hydrogen ion is implanted from a surface of a wafer on the active layer side with 2×10¹⁶-8×10¹⁶ atoms/cm² and an accelerating voltage of 50 keV or less to form an ion implantation layer on a surface layer of the wafer. After that, a wafer on the support substrate side is bonded at a room temperature, via a CVD oxide film, to the surface of the wafer on the active layer side, to make a bonded wafer. Next, the bonded wafer is subjected to a heat treatment at a heating temperature of 400-550° C. for a heating time of 1-60 minutes. By doing this, hydrogen bubbles are generated in the ion implantation layer so that the wafer on the active layer side is cleaved at the surface layer and an active layer remains on the surface of the CVD oxide film. Next, in order to enhance the bonding strength between the active layer and the CVD oxide film (the wafer on the support substrate side), the bonded wafer is subjected to a bonding heat treatment in an oxygen or nitrogen atmosphere at a temperature of 800° C. or above for a duration of 2 hours or above. This way, an SOI wafer of a hydrogen ion delamination method is manufactured. As the wafer on the active layer side, the first wafer having a CVD oxide film formed on a surface thereof can be adopted. The second wafer, of which the exposed surface is silicon, can also be adopted. The thickness of the active layer is, for example, 0.01-0.5 μm.

A CVD oxide film is an oxide film formed through a chemical reaction that occurs in a vapor phase or on the surface of a wafer when a growth gas (one kind or several kinds of compound gases and elementary gases made of the elements that constitute the material of the oxide film) is supplied to the surface of the wafer by using a CVD apparatus. For example, a CVD oxide film is formed on the surface of the first wafer by using a Chemical Vapor Deposition (CVD) method at a temperature of 400-450° C. As a growth gas, an inorganic silane (such as SiH₄) gas and an organic silane (such as TEOS) gas can be adopted. As a CVD apparatus, for example, a thermal CVD apparatus, a plasma CVD apparatus, an optical CVD apparatus, a laser CVD apparatus, and the like, can be adopted. A CVD oxide film becomes an embedded oxide film of a bonded wafer. Therefore, the thickness of the CVD oxide film, which is set according to its intended purpose, is generally 0.1-5.0 μm.

The bonding between the first wafer and the second wafer can also be performed, for example, at a room temperature (15-35° C.). As a condition of the heat treatment for enhancing the bonding strength (joint strength) of a bonded wafer, heating at a temperature of 800° C. or above, for example, 1000° C., for a duration of 2-20 hours can be adopted. As an atmosphere gas, for example, besides an oxygen gas, an inert gas such as nitrogen and argon can be adopted. As methods of film thinning for the case where film thinning of a bonded wafer is performed, grinding, polishing, etching, or the like, can be adopted.

The organic substance removal processing and the surface roughness reduction processing are performed either only on the bonding interface of the first wafer or on both the bonding interface of the first wafer and the bonding interface of the second wafer. The order in which the organic substance removal processing and the surface roughness reduction processing are performed is arbitrary. For example, the surface roughness reduction processing can be performed after the organic substance removal processing, and the reverse is also possible. The organic substance removal processing can be a cleaning or a heat treatment or both of the two. Of these, the cleaning process can be any one, any two, or even all of the following three: (1) an SC1 cleaning using an SC1 cleaning solution; (2) an SC2 cleaning using an SC2 cleaning solution; and (3) a two-step cleaning using a HF solution and an ozone water. In the SC1 cleaning, the SC1 cleaning solution, which is prepared by mixing NH₄OH, H₂O₂ and H₂O at a volume ratio of NH₄OH:H₂O₂:H₂O=1:1:7-1:2:7, is used. The wafer is soaked in the SC1 cleaning solution (solution temperature is 75-85° C.) for 10-20 minutes. By doing this, organic substances on the surface of the wafer are removed. When the SC1 cleaning is performed, the surface of the wafer is etched for about 4 nm, and therefore, particles on the surface of the wafer are also removed.

In the SC2 cleaning, the SC2 cleaning solution, which is made of a hydrochloric acid-hydrogen peroxide-water solution (HCl:H₂O₂:H₂O=1:1:6), is used. The wafer is soaked in the SC2 cleaning solution (solution temperature is a room temperature) for a few tens of seconds. By doing this, a silicon oxide film formed on the surface layer of the wafer is removed together with organic substances on the surface of the wafer. In the two-step cleaning, a HF solution, which is the first cleaning solution, and ozone water, which is the second cleaning solution, are sequentially used. In the first cleaning, the HF solution, which is obtained by dissolving HF in the water at a ratio of 0.1-1.0% by volume, is used. The wafer having organic substances to be removed from the bonding interface is soaked in the HF solution (solution temperature is 15-35° C.) for 1-5 minutes. By doing this, a silicon oxide film formed on the surface layer of the wafer is removed together with organic substances attached to the surface of the wafer. In the following second cleaning, the ozone water (solution temperature is 15-30° C.), which contains 5-30 ppm of ozone, is used. The wafer having organic substances to be removed from the bonding interface is soaked in the ozone water for 2-10 minutes. By doing this, organic substances attached to the surface of the wafer are decomposed and removed, and after that, a uniform flat oxide film is newly formed on the surface of the wafer.

As an atmosphere gas in the furnace of the heat treatment, an oxygen gas or a nitrogen gas can be adopted. Of these, an oxygen gas is the most desirable in that it allows formation of a protective film for post-processing, and it also allows protection of a weak bonding portion at the outmost periphery. When the temperature of the heat treatment of the wafer having organic substances to be removed is less than 200° C., organic substance removal is insufficient, which results in a weak bonding strength when the first wafer and the second wafer are bonded, and debonding from the bonding interface during film thinning in post-processing. The desirable temperature for the heat treatment is 300-500° C. When the temperature is in this range, a low cost is achievable due to being a low temperature process, while ensuring sufficient bonding strength when the wafers are bonded. In this way, by subjecting the wafer to a heat treatment at a temperature of 200° C. or above, organic substances that are attached to the bonding interface and hinder bonding can be removed (burned away).

As the surface roughness reduction processing to be performed at least on the CVD oxide film, a touch polish only, or a plasma treatment only, or both of the two, can be adopted. “Touch polish” is a polishing involving an extremely small polishing amount, such as a polishing using a CMP (Chemical Mechanical Polishing) method. The surface roughness of a CVD oxide film formed by using an atmospheric pressure CVD apparatus is about 1.0 nm in terms of RMS (Root Mean Square) roughness. This surface roughness is at the level that it is difficult to bond the surface as-is to the second wafer. Therefore, the surface of the CVD oxide film is touch polished so as to reduce the roughness of the surface to the level that bonding is possible. A CVD oxide film is soft as compared to a thermally oxidized film so that polishing speed is fast, and thus, can be easily flattened. When the polishing amount of the touch polish is below 200 Å, the polishing amount is too small. Therefore, the surface roughness of the polishing surface cannot be sufficiently reduced. On the other hand, when the polishing amount is above 2000 Å, it becomes easy for polishing pattern to be transcribed onto the surface, and it also undermines the uniformity in film thickness of the CVD oxide film that was achieved through polishing when the surface of the first wafer was polished. The desirable polishing amount of the touch polish is 200-500 Å. When the polishing amount is in this range, the surface roughness of the polishing surface can be sufficiently reduced, and costs for auxiliary materials used in polishing can be kept as low as possible.

In the plasma treatment, the number of OH-groups on the plasma treatment surface is increased to activate the surface, and wafer bonding takes place through a surface activation bonding (plasma bonding). Therefore, under such a condition, when the two wafers are bonded at a room temperature, the bonding interfaces are strongly bonded by hydrogen bonding. As a result, after that, even when a high temperature heat treatment for enhancing bonding strength is not performed, sufficiently high bonding strength is obtainable. In the case where the bonding heat treatment is performed, for example, a low temperature heat treatment at a heating temperature of 200-400° C. for about 2 hours is sufficient. Further, due to the increase in bonding strength through the plasma treatment, in the case where an SOI wafer is fabricated using a hydrogen ion delamination method, along with the delamination of the wafer on the active layer side, a terrace portion also becomes easy to peel off from the wafer on the active layer side. Therefore, the terrace portion can also be shrunk.

The terrace portion is a ring-shaped defective portion (a peripheral portion of the wafer on the support substrate side located at the periphery of the active layer) that inevitably occurs on the peripheral portion of the wafer on the support substrate side (for example, the second wafer), in the hydrogen ion delamination method, when the wafer on the active layer side (for example, the first wafer) is subjected to a heat treatment and delaminates. In the terrace portion, when delaminating, a portion of the wafer on the active layer side adheres to the surface and remains thereon, so that a so-called SOI island of an island-shaped adhered object appears. The SOI islands become particles during a device process, and can induce pattern defects and have negative effects on device property and performance. Therefore, as described above, when the bonding interface (the surface of the CVD oxide film) of at least one wafer is subjected to a plasma treatment, the bonding strength of the two wafers is enhanced, and a portion of the terrace portion also comes off along with the delamination of the wafer on the active layer side. Therefore, it is possible to shrink the terrace portion.

When the plasma treatment is performed, first, a target wafer, which has been subjected to a cleaning such as an RCA cleaning, is mounted in a vacuum chamber. After a gas for plasma is introduced into the chamber, the surface of the wafer is plasma treated by exposing it to a high-frequency plasma of about 100 W for about 5-10 seconds. As the gas for plasma, an oxygen gas can be adopted in the case where the surface is to be oxidized, and a hydrogen gas, an argon gas, or a mixed gas thereof can be adopted in the case where the surface is not to be oxidized. In addition, a mixed gas of a hydrogen gas and a helium gas can also be adopted.

Further, according to a non-limiting feature of the present disclosure, it is desirable that, in the organic substance removal processing, the cleaning is performed, and in the surface roughness reduction processing, the plasma treatment is performed after the touch polish. Specifically, prior to bonding the first wafer and the second wafer, of the first wafer and the second wafer, at least the bonding interface of the first wafer is cleaned. By doing this, at least organic substances attached to the surface of the CVD oxide film are removed. Further, of the first wafer and the second wafer, at least the bonding interface of the first wafer is sequentially subjected to a touch polish and a plasma treatment. By doing this, at least the surface roughness of the CVD oxide film can be further reduced. In particular, for example, in the case where cleaning is performed as the organic substance removal processing prior to a touch polish, foreign substances including organic substances attached during a CVD process can be removed.

### BRIEF DESCRIPTION OF THE DRAWINGS

The present disclosure is further described in the detailed description which follows, in reference to the noted plurality of drawings by way of non-limiting examples of exemplary embodiments of the present disclosure, in which like reference numerals represent similar parts throughout the several views of the drawings, and wherein:

FIG. 1 is a flowchart illustrating a manufacturing method of a bonded SOI wafer using a wafer bonding method according to a first embodiment of the present disclosure;

FIG. 2 is a flowchart illustrating a manufacturing method of a bonded SOI wafer using a wafer bonding method according to a second embodiment of the present disclosure;

FIG. 3 is a flowchart illustrating a manufacturing method of a bonded SOI wafer using a wafer bonding method according to a third embodiment of the present disclosure;

FIG. 4 is an X-ray topograph of a bonded wafer, which is plasma-bonded using a wafer bonding method according to a first comparative example;

FIG. 5 is an X-ray topograph of a bonded wafer, which is plasma-bonded using a wafer bonding method according to a second comparative example; and

FIG. 6 is an X-ray topograph of a bonded wafer, which is plasma-bonded using a wafer bonding method according to a first experimental example and a second experimental example.

### DETAILED DESCRIPTION OF THE INVENTION

The particulars shown herein are by way of example and for purposes of illustrative discussion of the embodiments of the present invention only and are presented in the cause of providing what is believed to be the most useful and readily understood description of the principles and conceptual aspects of the present disclosure. In this regard, no attempt is made to show structural details of the present disclosure in more detail than is necessary for the fundamental understanding of the present disclosure, the description is taken with the drawings making apparent to those skilled in the art how the forms of the present invention may be embodied in practice.

In following, the embodiments of the present disclosure are specifically explained.

### EMBODIMENTS

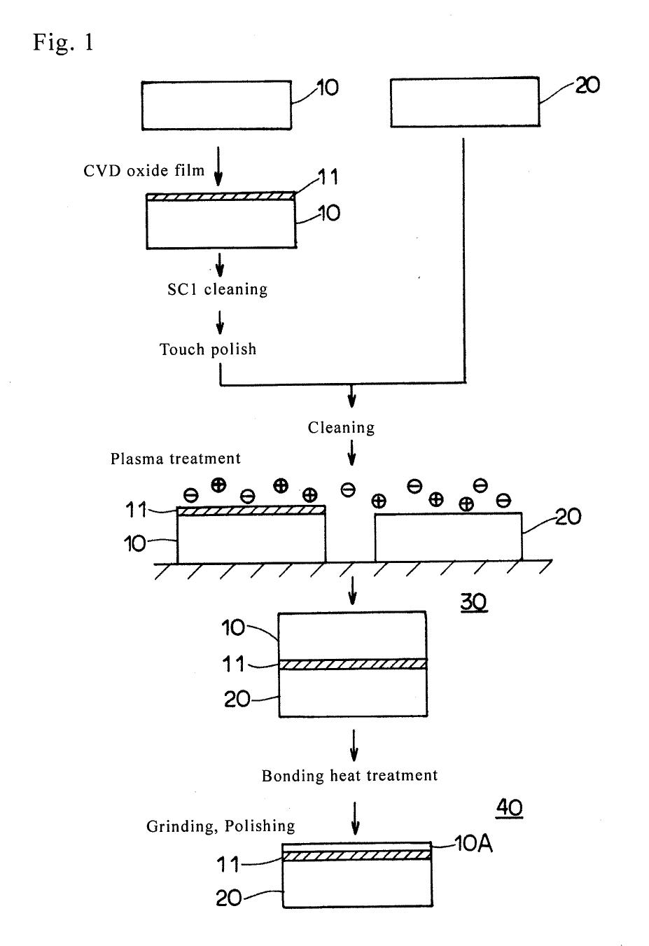

In the following, with reference to the flowchart of FIG. 1, a manufacturing method of a bonded SOI wafer using a wafer bonding method according to a first embodiment of the present disclosure is explained. As illustrated in the flowchart of FIG. 1, first, a p-type single crystal silicon ingot having a predetermined amount of boron added therein is pulled using a CZ method. After that, the single crystal silicon ingot is subjected to block cutting, slicing, chamfering, mirror polishing, and the like. By doing this, a wafer (first wafer) 10 for an active layer and a wafer (second wafer) 20 for a support substrate are obtained each having a thickness of 725 μm, a diameter of 200 mm, a resistivity of 10-20 Ωcm, being of a p-type, and having one surface mirror-finished. After that, the wafer 10 for an active layer is put into an atmospheric pressure CVD apparatus. A TEOS (tetraethoxysilane) gas is supplied into the furnace. At a heating temperature of 450° C., a CVD oxide film 11 having a thickness of 0.2 μm is grown on the surface of the wafer 10 for an active layer by using a chemical vapor deposition (CVD) method.

Next, the wafer 10 for an active layer is soaked for 10 minutes in an SC1 cleaning solution (75° C.) prepared with a volume ratio of NH₄OH:H₂O₂:H₂O=1:2:7. By doing this, organic substances and particles on the surface of the wafer 10 for an active layer are removed. After that, the wafer 10 for an active layer is transferred to a single-wafer type single-surface polishing apparatus, and a touch polish is performed using a CMP, which involves an extremely small polishing amount. Here, the single-surface polishing apparatus is equipped with a polishing table and a polishing head. The polishing table has a polishing cloth adhered to an upper surface thereof. The polishing head is arranged right above the polishing table and has the wafer for an active layer attached on a lower surface thereof.

When polishing is performed, the wafer 10 for an active layer is attached to the lower surface of the polishing head with the CVD oxide film 11 facing downward. The polishing head is gradually lowered, and a touch polish is performed at 30 rpm with a polishing amount of 300 Å. During this, a polishing liquid is supplied to the polishing cloth at a feed rate of 0.5 liter/minute, and polishing time is 5 minutes. For the polishing liquid, an alkaline polishing liquid containing fine polishing particles of CeO₂ (cerium oxide) and the like is used. By doing this, the surface roughness of the CVD oxide film is reduced to the extent that bonding with a silicon is possible.

Next, the surface of the CVD oxide film 11 to be used as the bonding interface of the wafer 10 for an active layer and the surface to be used as the bonding interface of the wafer 20 for a support substrate are subjected to a RCA cleaning. The cleaning condition is to perform twice the same SC1 cleaning as described above for 10 minutes. After that, the surface of the CVD oxide film 11 to be used as the bonding interface of the wafer 10 for an active layer and the surface to used as the bonding interface of the wafer 20 for a support substrate are subjected to a plasma treatment. Specifically, the wafer 10 and the wafer 20 are mounted in a vacuum chamber with the bonding interfaces facing upward. After that, in an oxygen atmosphere, the surfaces are exposed to high-frequency plasma of 100 W for 30 seconds to be plasma treated. By doing this, the plasma-treated surfaces have an increased number of OH-groups and become activated.

Next, with the surface of the CVD oxide film 11 of the wafer 10 for an active layer and the surface (mirror surface) of the wafer 20 for a support substrate as the bonding surfaces (overlay surfaces), the wafer 10 and the wafer 20 are bonded at a room temperature using a commonly known jig. By doing this, a bonded wafer 30 is formed. As described above, the plasma treated surfaces have an increased number of OH-groups and become activated. Therefore, under such a condition, when the wafer 10 and the wafer 20 are bonded at a room temperature, the bonding interfaces are strongly bonded through hydrogen bonding. As a result, the bonding strength (joint strength) of the wafer 10 and the wafer 20 at a room temperature can be enhanced. By doing this, even when the later described high temperature heat treatment for enhancing the bonding strength is not performed, the bonding of the wafer 10 and the wafer 20 is sufficiently strong. In this way, by bonding the wafer 10 for an active layer and the wafer 20 for a support substrate, an embedded CVD oxide film having a thickness of 0.2 μm, which is a CVD oxide film 11, is formed between the two wafers.

Next, the bonded wafer 30 is subjected to a heat treatment for enhancing the bonding strength in an atmosphere of an oxygen gas at a temperature of 400° C. for a heating time of 10 hours. As a result, the bonding strength of the wafer 10 for an active layer and the wafer 20 for a support substrate is further enhanced. Next, the bonded wafer 30 is ground and polished from the side of the wafer 10 for an active layer to perform film thinning. By doing this, the wafer 10 for an active layer becomes an active layer 10A having a thickness of 10 μm. In this way, a bonded SOI wafer 40 is manufactured in which the CVD oxide film 11 having a thickness of 0.2 μm, and the active layer 10A having a thickness of 10 μm, are sequentially laminated on the surface of the wafer 20 for a support substrate.

In this way, prior to bonding the wafer 10 for an active layer and the wafer 20 for a support substrate, the surface (bonding interface) of the CVD oxide film 11 of the wafer 10 for an active layer is subjected to an SC1 cleaning. Therefore, the amount of organic substances attached to the surface of the CVD oxide film 11 can be reduced. After that, the surface of the CVD oxide film 11, which has had the organic substances removed, is subjected to a touch polish and a plasma treatment. Therefore, the surface roughness of the CVD oxide film 11 is reduced. As a result, even for a wafer bonding between a CVD oxide film and a silicon, for which bonding is difficult, bonding becomes possible, and void occurrence is also inhibited. And, since a cleaning for removing organic substances is performed prior to a touch polish, foreign substances including organic substances attached during a CVD process can be removed.

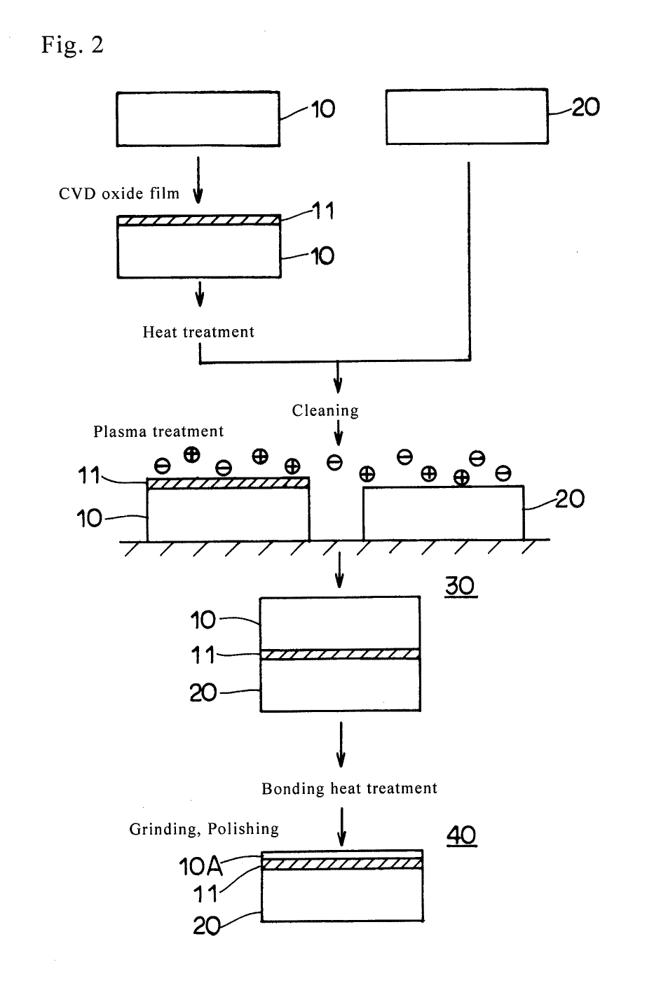

Next, with reference to the flowchart of FIG. 2, a manufacturing method of a bonded SOI wafer using a wafer bonding method according to a second embodiment of the present disclosure is explained. As illustrated in the flowchart of FIG. 2, the feature of the wafer bonding method according to the second embodiment is that, in place of the SC1 cleaning (organic substances removal) and the touch polish (surface roughness reduction) that are sequentially performed to the wafer 10 for an active layer after film formation of the CVD oxide film 11 in the first embodiment, a heat treatment in an atmosphere of a mixed gas of nitrogen and oxygen is adopted. Specifically, the wafer 10 for an active layer having had the CVD oxide film 11 formed thereon is put into a furnace of an annealing apparatus, and is heat treated in an atmosphere of a mixed gas of nitrogen and oxygen at a temperature of 800° C. for 10 hours.

After the heat treatment, it is also possible to subject the surface of the CVD oxide film 11 to a touch polish under the same condition as in the first embodiment. In that case, the surface roughness of the CVD oxide film 11 is further reduced, and the bonding strength of the wafer 10 and the wafer 20 can be enhanced as compared to the case of the first embodiment. Further, it is also possible to subject the surface of the CVD oxide film 11 of the wafer 10 for an active layer before the heat treatment to an SC1 cleaning under the same condition as in the first embodiment. In that case, the removal rate of the organic substances on the surface of the CVD oxide film 11 can be increased.

In this way, prior to bonding the wafer 10 for an active layer and the wafer 20 for a support substrate, the wafer 10 for an active layer is subjected to a predetermined heat treatment. Therefore, organic substances attached to the surface of the CVD oxide film 11 are burned away. Furthermore, unevenness of the surface due to organic substances is reduced, and the surface is flattened by a viscous flow of the oxide film. Thereby, the surface roughness of the CVD oxide film 11 is also reduced. The rest of the configuration, functions and effects are the same as in the first embodiment, and therefore, the description thereof is not repeated.

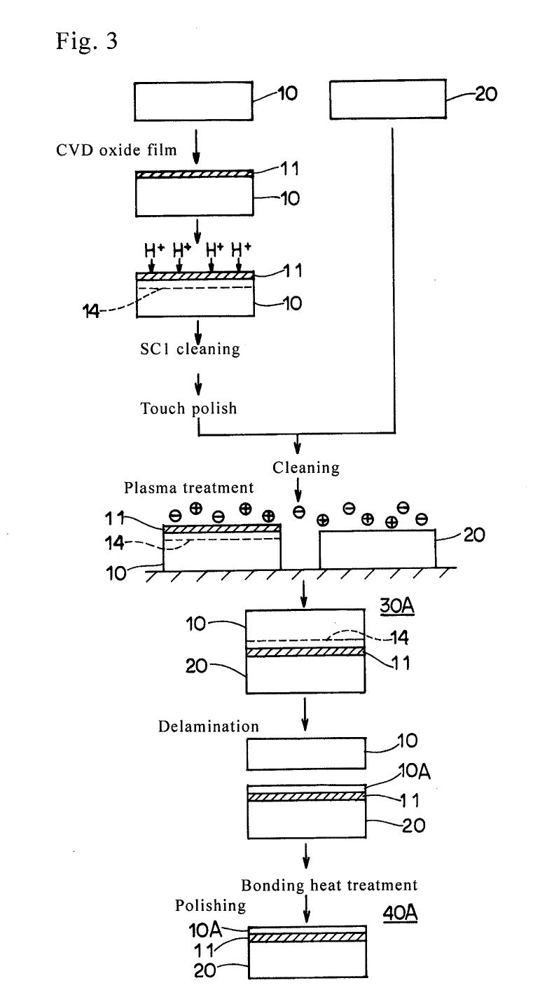

Next, with reference to the flowchart of FIG. 3, a manufacturing method of a bonded SOI wafer using a wafer bonding method according to a third embodiment of the present disclosure is explained. As illustrated in the flowchart of FIG. 3, the feature of the wafer bonding method according to the third embodiment is that, a hydrogen ion delamination method is adopted for manufacturing a bonded SOI wafer 40A in the first embodiment. Specifically, after the film formation process of the CVD oxide film 11, the wafer 10 for an active layer is put into a furnace of a medium current ion implantation apparatus. Here, through the CVD oxide film 11, hydrogen ions are implanted under an acceleration voltage of 50 keV to a location of a predetermined depth from the surface of the wafer 10 for an active layer. By doing this, a hydrogen ion implantation region 14 is formed. The dose amount is 1.2×10¹⁷ atoms/cm², and the ion implantation depth (Rp) is about 0.5 μm. After the ion implantation, the wafer 10 for an active layer is sequentially subjected to an SC1 cleaning process and a touch polish process. After that, the bonding interfaces of the wafer 10 and the wafer 20 are plasma treated. After that, the wafer 10 and the wafer 20 are bonded at a room temperature to make a bonded wafer 30A.

In the third embodiment, after the bonding, the wafer 10 for an active layer is subjected to a delamination heat treatment. More specifically, the bonded wafer 30A is put into a delamination heat treatment apparatus, and is heat treated at a furnace temperature of 500° C. in an atmosphere of a N₂ gas (an argon gas or an oxygen gas can also be used). The duration of the heat treatment is 30 minutes. By doing this, a low temperature heat treatment is performed in which an active layer 10A remains on the bonding interface side of the wafer 20 for a support substrate, and the wafer 10 for an active layer is delaminated from the hydrogen ion implantation region 14. After that, the delaminated wafer 10 for an active layer, by having its surface re-polished, can be used again as a wafer 20 for a support substrate or a wafer 10 for an active layer. The bonded wafer 30A after the delamination is subjected to a heat treatment for enhancing the bonding strength. After that, the surface of the active layer 10A is final polished under a predetermined mirror polishing condition, and a bonded SOI wafer 40A is manufactured.

In this way, since the wafer bonding method of the present disclosure is applied to the manufacture of the bonded SOI wafer 40A that uses a hydrogen ion delamination method, the film thickness uniformity of the active layer 10A can be improved. The rest of the configuration, functions and effects are the same as in the first embodiment, and therefore, the description thereof is not repeated.

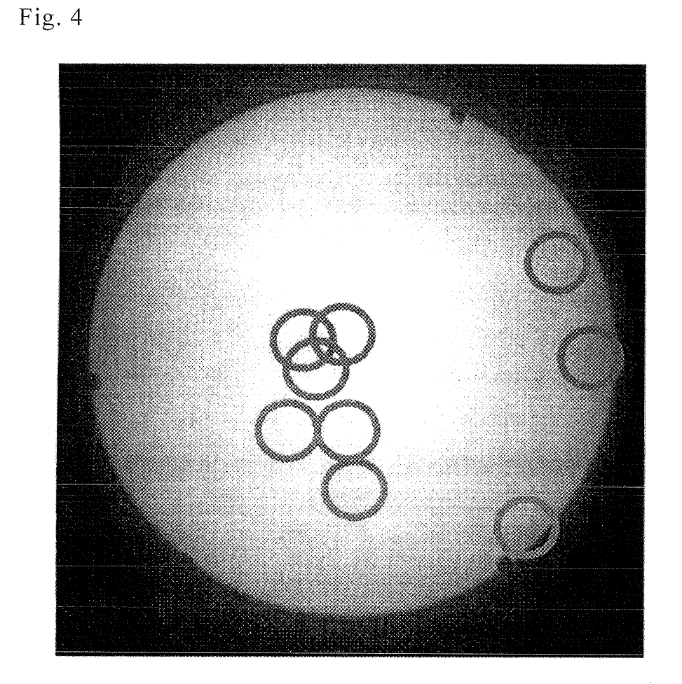

Experiments have been conducted to compare actual results based on a conventional method and the method of the present disclosure, regarding removal of organic substances attached to the surface of the CVD oxide film of the wafer for an active layer and void occurrence in the bonded wafer, and the results of the experiments are reported here. The conditions of the experiments are based on the first embodiment and the second embodiment. A commonly-used gas chromatography mass spectrometer (GC-MS) is adopted for the evaluation of organic substance removal. And a commonly-used infrared void apparatus is adopted for the examination of voids. In FIG. 4-FIG. 6, voids exist inside a circle of the bonded wafer.

### First Comparative Example

On the surface of the wafer for an active layer obtained by using the method according to the first embodiment, a CVD oxide film having a thickness of 0.2 μm was formed. After that, the amount of organic substances attached to the surface of the CVD oxide film was measured. As a result, it was confirmed that 1.18 ng/cm² of organic substances were attached to the surface of the CVD oxide film. Next, it was attempted to bond at a room temperature this wafer for an active layer and the wafer for a support substrate obtained in the first embodiment, but the bonding failed. Further, with respect to a wafer for an active layer and a wafer for a support substrate of the first comparative example, which were prepared separately from the above, the two bonding interfaces were plasma treated, and after that, the two wafers were bonded to make a bonded wafer. Void examination of the bonded wafer was performed. As a result, 9 voids were detected (FIG. 4).

### Second Comparative Example

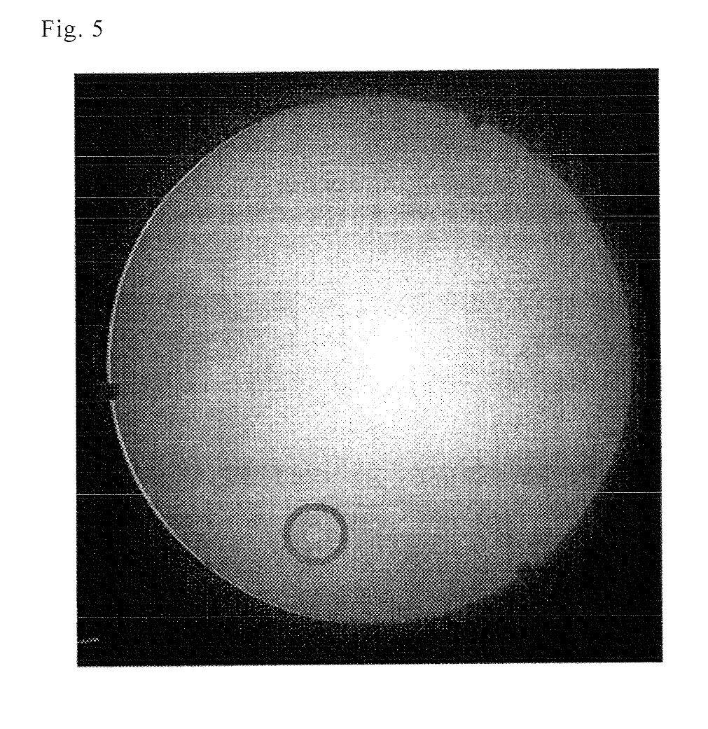

After the formation of a CVD oxide film on the surface of a wafer for an active layer, the surface of the CVD oxide film was subjected to an SC1 cleaning. As a result, 0.02 ng/cm² of organic substances were attached to the surface of the CVD oxide film. Next, bonding between this wafer for an active layer and the wafer for a support substrate was performed at a room temperature. But, the same as in the first comparative example, the bonding failed. Further, with respect to a wafer for an active layer and a wafer for a support substrate of the second comparative example, which were prepared separately from the above, the two bonding interfaces were plasma treated, and after that, the two wafers were bonded. Void occurrence in the resulting bonded wafer was examined. As a result, one void was detected (FIG. 5). The rest of the experimental conditions and evaluation conditions are the same as in the first comparative example, and therefore, the description thereof is not repeated.

### First Experimental Example

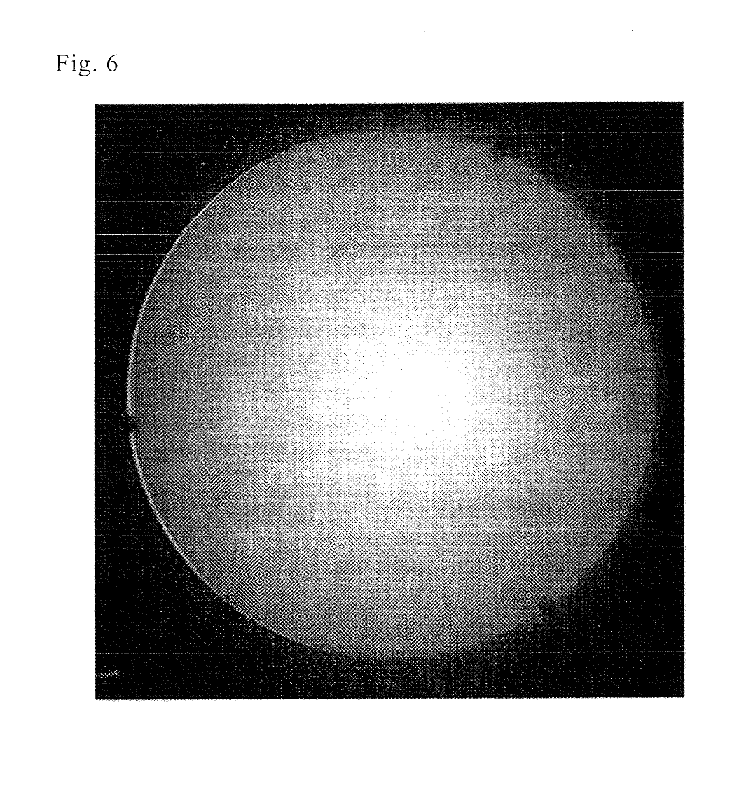

On the surface of the wafer for an active layer obtained by using the method according to the first embodiment, a CVD oxide film having a thickness of 0.2 μm was formed. After that, the surface of the CVD oxide film was subjected to an SC1 cleaning, and then, the cleaned surface was subjected to a touch polish. As a result, the amount of organic substances attached to the surface of the CVD oxide film was reduced to below 0.01 ng/cm². Next, this wafer for an active layer and the wafer for a support substrate were bonded at a room temperature, and the void occurrence of the resulting bonded wafer was examined. As a result, no void was detected (void free). Further, with respect to a wafer for an active layer and a wafer for a support substrate of the first experimental example, which were prepared separately from the above, the two bonding interfaces were plasma treated, and the two wafers were bonded to make a bonded wafer. Void occurrence was examined. The result was void free, the same as in the above described bonding in which no plasma treatment was performed (FIG. 6).

### Second Experimental Example

On the surface of the wafer for an active layer, a CVD oxide film was formed. After that, the wafer for an active layer was subjected to heat treatment. As a result, the amount of organic substances attached to the surface of the CVD oxide film was below 0.01 ng/cm², the same as in the first experimental example. Next, this wafer for an active layer and the wafer for a support substrate were bonded at a room temperature to make a bonded wafer. Void occurrence in the bonded wafer was examined. As a result, several voids were detected. Further, with respect to a wafer for an active layer and a wafer for a support substrate of the second experimental example, which were prepared separately from the above, the two bonding interfaces were plasma treated. After that, the two wafers were bonded to make a bonded wafer. Void occurrence in the bonded wafer was examined. The result was void free, the same as in the first experimental example (FIG. 6). The rest of the experimental conditions and evaluation conditions are the same as in the first experimental example, and therefore, the description thereof is not repeated.

The present disclosure is useful as a substrate wafer such as an MPU (Micro Processing Unit), a consolidated DRAM (Dynamic Random Access Memory), a CIS (CMOS Image Sensor), and the like.

It is noted that the foregoing examples have been provided merely for the purpose of explanation and are in no way to be construed as limiting of the present disclosure. While the present invention has been described with reference to exemplary embodiments, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular structures, materials and embodiments, the present invention is not intended to be limited to the particulars disclosed herein; rather, the present invention extends to all functionally equivalent structures, methods and uses, such as are within the scope of the appended claims.

The present invention is not limited to the above described embodiments, and various variations and modifications may be possible without departing from the scope of the present invention.

What is claimed is:

1. A wafer bonding method for bonding a first wafer and a second wafer via a CVD (Chemical Vapor Deposition) oxide film, the first wafer having the CVD oxide film formed on a surface thereof, and the second wafer being made of silicon, the method comprising:
as a pre-processing of the bonding, out of a bonding interface of the first wafer and a bonding interface of the second wafer, subjecting at least the bonding interface of the first wafer to an organic substance removal processing and a surface roughness reduction processing, the organic substance removal processing being at least one of a cleaning and a heat treatment;
when at least one of the cleaning and the heat treatment is the cleaning, performing the cleaning using any one of an SC1 cleaning solution, an SC2 cleaning solution and a two-step cleaning solution, the two-step cleaning solution being made of a HF solution for a first cleaning and an ozone water for a second cleaning, the second cleaning being performed after the first cleaning;
when at least one of the cleaning and the heat treatment is the heat treatment, performing the heat treatment in an atmosphere of one of an oxygen gas and a nitrogen gas at a temperature of 200° C. or above;
performing the surface roughness reduction processing using at least one of a touch polish and a plasma treatment;
performing the touch polish using a polishing amount of 200-2000 Å; and
performing the plasma treatment by exposing at least the bonding interface of the first wafer to high-frequency plasma of 50-500 W for 5-60 seconds.

2. The wafer bonding method according to claim 1, wherein:
in the organic substance removal processing, the cleaning is performed; and
in the surface roughness reduction processing, the plasma treatment is performed after the touch polish.
